(19) United States
(12) Patent Application Publication
(10) Pub. No.: US 2003/0111675 A1
(43) Pub. Date: Jun. 19, 2003

(54) Doped absorption for enhanced responsivity for high speed photodiodes

(75) Inventor: Jie Yao, Princeton, NJ (US)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: JDS Uniphase Corporation, San Jose, CA

(21) Appl. No.: 10/304,202

(22) Filed: Nov. 26, 2002

Related U.S. Application Data
(60) Provisional application No. 60/333,616, filed on Nov. 27, 2001.

(51) Int. Cl. H01L 27/148

(52) U.S. Cl. 257/233

(57) ABSTRACT

A photodiode with a semiconductor intrinsic light absorption layer has at least one p-doped light absorption layer or an n-doped light absorption layer, and preferably both. The diode also has a cathode electrode and an anode electrode electrically couple with the p-doped light absorption layer or the n-doped light absorption layer.

### CROSS-REFERENCE TO RELATED APPLICATIONS

This applications claims priority of U.S. Provisional Patent Application No. 60/333,616 filed on Nov. 27, 2001, entitled “Doped Absorption for Enhanced Responsivity-Bandwidth Limit and Doped Quarternary Stack for the Reduction of Carrier Trapping in High-Speed High Sensitivity Photodiodes” which is incorporated herein by reference for all purposes.

### FIELD OF THE INVENTION

This invention relates to photodiodes, such as PIN photodiodes and avalanche photodiodes (APDs); and, more particularly to a diode structure that provides an enhanced responsivity and, therefore, enhanced sensitivity without compromising speed.

### BACKGROUND OF THE INVENTION

Various photodiode structures are known and the goal in designing these structures depends upon which response characteristics are to be optimized. By way of example, U.S. Pat. No. 5,818,096 in the names of Ishibashi, et al. issued Oct. 6, 1998 entitled Pin Photodiode with Improved Frequency Response and Saturation Output is incorporated here by reference. Other references in the field related to semiconductor devices are:

S. M. Sze, Semiconductor Devices—Physics And Technology, Section 7.4 on p.283.

Ben. G. Streetman, Solid State Electronic Devices, 3rd edition, Sec. 6.3.3 on pp.217-219, with emphasis on FIGS. 6-17.

K. Kato et al., “Design of Ultrawide-Band, High-Responsivity p-i-n Photodetectors” IEICE Trans. Electron., Vol.E76-C, No.2, pp. 214-221, February 1993).

Kazutoshi Kato, “Ultrawide-Band/High-Frequency Photodetectors” IEEE Trans. Microwave Theory and Techniques, pp.1265-1281, Vol. 47, No. 7, 1999.

S. L. Chuang, Physics of Optoelectronic Devices, Wiley Series in Pure and Applied Optics, John Wiley and Sons, 1995.

J. N. Hollenhorst, “Frequency Response Theory for Multilayer Photodiodes” Journal of Lightwave Technology, Volume 8, Issue 4, pp. 531-537, 1990.

The pin photodiode taught by Ishibashi is a structure capable of improving the frequency response and the saturation output while maintaining the small RC time constant.

In FIG. 2b of the Ishibashi patent a band diagram of a photodiode in one embodiment has an undoped intrinsic traveling layer serving as a non-absorbing carrier layer. FIG. 9b of the '096 patent is described to be prior art, in contrast with the invention Ishibashi et al. The only absorption layer within this prior art of FIG. 9b, embodiment described and shown by Ishibashi et al., is intrinsic carrier traveling layer, which is light-absorbing.

In contrast to the teaching and invention of Ishibashi et al, and in contrast with the device that he describes as prior art, this invention provides a doped absorption structure for enhanced responsivity bandwidth by creating at least one of the p-doped or n-doped layers for absorption of light in addition to having a commonly used intrinsic light-absorbing layer. The electrodes are made of high-bandgap material and hence non-absorbing, while the absorption layers are made of low-bandgap material.

The device in accordance with this invention can be viewed as a conventional PIN having n and p absorption layers. In contrast Ishibashi in the U.S. Pat. No. 5,818,096 is absent an n-absorption layer, AND, more importantly, is absent intrinsic absorption, small bandgap layer in accordance with this invention and provides instead an intrinsic non-absorbing (large bandgap) carrier transport layer.

The Ishibashi et al. disclosure teaches a pin diode with high-saturation power. This is at a cost of low responsivity and hence low sensitivity. The design in accordance with this invention provides for high-responsivity and hence high-sensitivity at a cost of lower-saturation power. Hence the structure and response characteristics of the invention described herein, are substantially different than that of Ishibashi et al.

The operating characteristics of a conventional pin falls somewhere in between Ishibashi's design and the device in accordance with this invention; notwithstanding, all three designs are high-speed devices. Although the doing in FIGS. 1 and 2 is shown to be uniform, they need not be.

### SUMMARY OF THE INVENTION

In accordance with the invention, there is provided, a photodiode comprising a semiconductor intrinsic light absorption layer; at least one of a p-doped light absorption layer and an n-doped light absorption layer;

and, a cathode electrode and an anode electrode electrically couple with the p-doped light absorption layer or the n-doped light absorption layer.

In a preferred embodiment the total thickness of the doped and intrinsic light absorption layers is greater than v/(2f_{3-dB}), where v is the drift velocity of either the electron or the hole, whichever is smaller, in the intrinsic light-absorbing layer at operating bias, wherein f_{3-dB} is the frequency at which the amplitude of responsivity of the photodetector is reduced to 1/\sqrt{2} of its DC (low-frequency) value. When operated at high bias, the carrier drift velocity reaches the saturation value.

### BRIEF DESCRIPTION OF THE DRAWINGS

Exemplary embodiments of the invention will now be described in conjunction with the drawings in which:

FIG. 1 is a band diagram for a pin photodiode with doped absorption according to the first embodiment of the present invention; and,

FIG. 2 is a band diagram for an avalanche photodiode (APD) with doped absorption layer according to an embodiment of the invention.

### DETAILED DESCRIPTION

Unfortunately, in a conventional pin, there is a tradeoff between speed and responsivity. To achieve high-speed, a device requires thin absorption layers so that carriers can pass through quickly before they enter the electrode. On the other hand, to achieve high responsivity, a thick absorption layer is required so that most or all photon energy is absorbed and few or none of photons are lost. This is true whether the incident light is normal to or in-plane with the epitaxial layers. As a result, for a conventional pin, the speed X responsivity product is essentially a constant for surface-normal light incidence, and a similar tradeoff applies to waveguide pin diode. The device described by Ishibashi is very poor with regard to its responsivity and sensitivity but higher saturation power is attained. Since the speed of a communication system is set by industrial standards, for example, at 10G bit/second, 40G bits/second, etc., hereafter, the term responsivity shall be used interchangeably with the speed X responsivity product at a fixed standard speed of the communication system.

In accordance with this invention, surprisingly, the speed x responsivity limit can be increased; this is of paramount importance for a high-speed avalanche photodiodes (APDs); in this instance doped absorption layers can be used; in a preferred embodiment, p-doped absorption layers are most advantageous. This structure is extremely easy to manufacture and relatively simple changes are required from that of a conventional pin/APD diode; notwithstanding the device in certain instances is significantly superior. The doped absorption layers work both as electrodes and as absorption layers, so that the carriers of the same polarity as the dopant do not have to travel across it to become collected. As long as the doped absorption layers are not so thick that the time it takes for the charged carriers to diffuse out of the doped absorption layer is equal to or longer than the required photodiode response time for a high-speed photodiode, carriers of the opposite polarity can very rapidly diffuse out of the layers, adding very little transit-time to that of a conventional pin/APD diode. The doped absorption layers, of course, add to absorption, especially with its enhanced absorption due to doping. Hence, with the doped-absorption structure of this invention, a higher speed x responsivity limit is achieved than the conventional pin/APD diodes. For example, it is believed that a 40G-Hz pin diode, namely, a photodiode whose 3-dB frequency in photocurrent response is 40 GHz, designed with an n and p doped absorption layer in accordance with a preferred embodiment, can achieve a 20% increase in responsivity with little or no compromise in bandwidth, i.e., keeping the 3-dB frequency of the pin diode at 40 GHz, as a very conservative estimate. Similarly, the responsivity of a SAM-APD with doped absorption in addition to the standard intrinsic absorption layer is higher than that of the corresponding conventional SAM-APD without doped absorption layer at the same bandwidth and at the same multiplication gain.

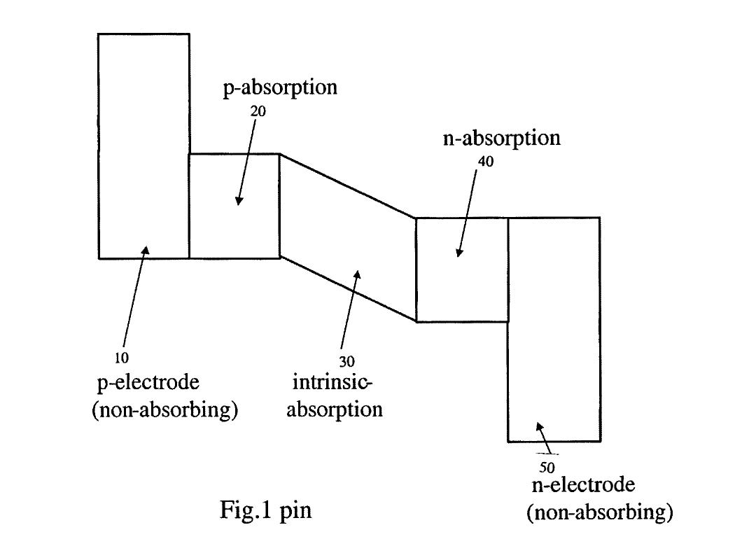

Turning now to FIG. 1, a band diagram for a 40 GHz PIN photodiode according to a first preferred embodiment of the invention is shown having an InGaAs intrinsic absorption layer 30 having a thickness of approximately 0.5-0.6 microns, sandwiched between a 0.2-0.25 micron p-doped InGaAs absorption layer 20 and a 0.020-0.025 micron-thick n-doped InGaAs absorption layer 40. The n-absorption layer is not essential. Accurate numbers are material and crystal-growth dependent, but it is preferable to be in the approximate range given above for the material system of InGaAs latticed-matched in InP. Non-absorbing n and p InP electrodes 10 and 50 are shown at opposite ends. Preferably the entire device structure is lattice matched to InP, however this is not a requirement. For an electron-hole pair photo-generated in the intrinsic region, the electrons are collected by the n-absorption layer which also serves as an n-electrode, and the holes are collected by the p-absorption layer which serves as p-electrode, having only to travel across the intrinsic absorption, same as the conventional pin diode. By way of this design and its dimensions, added absorption is afforded mainly from the p-doped absorption layer. The doped absorption layers can, although they do not have to, be made of the same kind of material as the intrinsic absorption layer while incorporating dopants of the corresponding type (for example, Zn or Be for p-doping and S for n-doping), resulting in slightly higher absorption than the intrinsic layer. For an electron photo-generated in the p-absorption layer, it will very rapidly diffuse out of that layer and traverse the intrinsic absorption layer then to be collected by the n-absorption layer functioning as n-electrode. This process is a fractionally slower than a conventional pin, since an electron generated in the p-doped absorption layer must traverse the entire intrinsic region. However, with slightly reduced intrinsic absorption layer thickness, which is necessary only if diode speed is transit time limited, the added absorption in the p-absorption layer more than offsets the slight reduction from the slightly reduced thickness of the intrinsic absorption layer. If the diode speed is not transit-time limited, the slight reduction in the thickness of the intrinsic absorption layer is not necessary. This is similar for the holes generated in the n-doped absorption layer. Typically, the maximum thickness of the intrinsic light-absorbing layer in a corresponding conventional 40 GHz pin photodiode without the doped absorption layer(s), is only about 0.6 micron. The total thickness of all the doped and intrinsic absorption layers in accordance with this invention is at least 0.75 micron, 25% larger than its corresponding conventional pin diode. Overall, the pin with doped absorption layers breaks through the speed x responsivity limit imposed by a conventional pin diode.

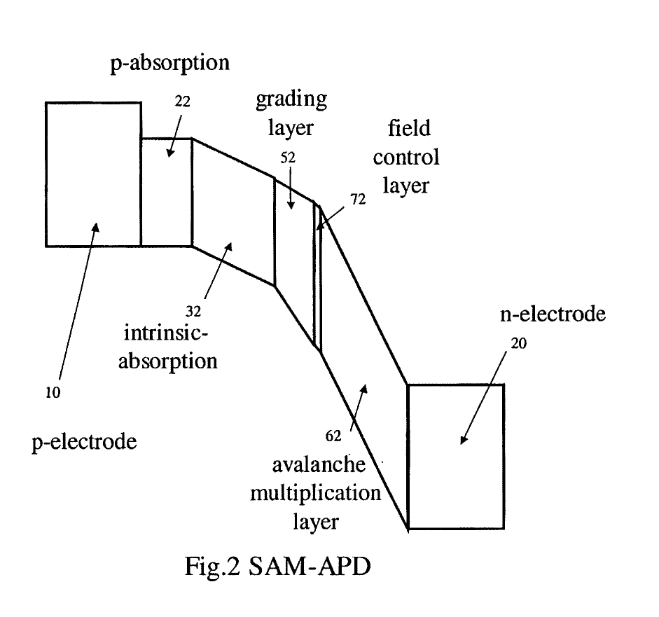

FIG. 2 illustrates a band diagram of a high-speed APD with separate absorption and multiplication (SAM) in the material system of InGaAs—InAlGaAs—InAlAs, in this embodiment all lattice-matched to InP according to a second preferred embodiment of the invention. The APD shown has a p-doped InGaAs absorption layer 22, followed by an InGaAs intrinsic absorption layer 32, followed by the grading 52, field-control 72 and multiplication 62 layers in a standard SAM-APD. The n-absorption layer 20 is not required. Accurate numbers are even more material and crystal-growth dependent, and that is why they are not shown. Non-absorbing n and p InP electrodes are shown at opposite ends. The entire device structure is lattice matched to InP, but it does not have to. For an electron-hole pair photo-generated in the intrinsic region, the holes are collected by the p-absorption layer, which also serves as part of the p-electrode, while the electrons drift through the grading layer, get accelerated by the field control layer, and cause avalanche multiplication in the multiplication layer. The secondary holes generated by the avalanche process come back into the absorption layers, having only to traverse the intrinsic portions to get collected by the p-absorption layer serving as part of the p-electrode, same as the conventional SAM-APD. By way of this embodiment, added absorption is afforded mainly from the p-doped absorption layer, without any increase in unwanted secondary-hole drift time across the intrinsic absorption region characteristic of conventional SAM-APDs. For an electron photo-generated in the p-absorption layer, it will very rapidly diffuse out of that layer and traverse the intrinsic absorption layer then to participate in the avalanche process. Completely analogous to the pin diode, this process is a fractionally slower than a conventional SAM-APD, since an electron generated in the p-doped absorption layer must traverse the entire intrinsic region. However, with slightly reduced intrinsic absorption layer thickness, which is necessary only if diode speed is transit time limited, the added absorption in the p-absorption layer more than offsets the slight reduction from the slightly reduced thickness of the intrinsic absorption layer. If the diode speed is not transit-time limited, (avalanche-limited, or RC-limited, for example) the slight reduction in the thickness of the intrinsic absorption layer is not necessary. It should be understood that the maximum allowed thickness of the intrinsic light-absorbing layer in the corresponding conventional SAM-APD photodiode, is noticeably smaller than the total thickness of all the p-doped and intrinsic absorption layers in the device in accordance with this invention at the same bandwidth and at the same multiplication gain. Overall, the SAM-APD with doped absorption layers breaks through the speed x responsivity (gain) limit that has been imposed by conventional SAM-APDs.

What is claimed is:

1. A photodiode with comprising:
a semiconductor intrinsic light absorption layer;
at least one of a p-doped light absorption layer and an n-doped light absorption layer;
and, a cathode electrode and an anode electrode electrically couple with the p-doped light absorption layer or the n-doped light absorption layer.

2. A photodiode as defined in claim 1, wherein the semiconductor intrinsic layer and the at least the p-doped light absorption layer or the n-doped light absorption layer are sandwiched between the cathode and anode electrodes.

3. A photodiode as defined in claim 1, wherein the intrinsic light absorption layer is disposed between and adjacent to the p-doped light absorption layer and the n-doped light absorption layer.

4. A photodiode as defined in claim 1, wherein the light absorption layers consist a p-doped light absorption layer, and the intrinsic light absorption layer, said layers being adjacent to one another.

5. A photodiode as defined in claim 1, wherein the light absorption layers consist an n-doped light absorption layer, and the intrinsic light absorption layer, said layers being adjacent to one another.

6. A photodiode as defined in claim 1, wherein the total thickness of the doped and intrinsic light absorption layers is greater than v/(2f_{3-dB}), where v is the saturation drift velocity of either the electron or the hole, whichever is smaller, in the intrinsic light-absorbing layer, wherein f_{3-dB} is the frequency at which the amplitude of responsivity of the photodetector is reduced to 1/\sqrt{2} of its DC low-frequency value.

7. A photodiode as defined in claim 3, wherein the total thickness of the doped and intrinsic light absorption layers is greater than v/(2f_{3-dB}), where v is the saturation drift velocity of either the electron or the hole, whichever is smaller, in the intrinsic light-absorbing layer, wherein f_{3-dB} is the frequency at which the amplitude of responsivity of the photodetector is reduced to 1/\sqrt{2} of its DC low-frequency value.

8. A photodiode as defined in claim 4, wherein the total thickness of the doped and intrinsic light absorption layers is greater than v/(2f_{3-dB}), where v is the saturation drift velocity of either the electron or the hole, whichever is smaller, in the intrinsic light-absorbing layer, wherein f_{3-dB} is the frequency at which the amplitude of responsivity of the photodetector is reduced to 1/\sqrt{2} of its DC low-frequency value.

9. A photodiode as defined in claim 5, wherein the total thickness of the doped and intrinsic light absorption layers is greater than v/(2f_{3-dB}), where v is the saturation drift velocity of either the electron or the hole, whichever is smaller, in the intrinsic light-absorbing layer, wherein f_{3-dB} is the frequency at which the amplitude of responsivity of the photodetector is reduced to 1/\sqrt{2} of its DC low-frequency value.

10. A photodiode as defined in claim 1, wherein the total thickness of the doped and intrinsic light absorption layers is greater than v/(2f_{3-dB}), where v is the drift velocity of either the electron or the hole, whichever is smaller, in the intrinsic light-absorbing layer under operating bias, and wherein f_{3-dB} is the frequency at which the amplitude of responsivity of the photodetector is reduced to 1/\sqrt{2} of its DC low-frequency value.

11. A photodiode as defined in claim 1, wherein the presence of the doped absorption layer increases the responsivity x bandwidth product.

12. A photodiode as defined in claim 1 including an avalanche multiplication layer, wherein the responsivity x avalanche-multiplication-gain x bandwidth product exceeds the responsivity x avalanche-multiplication-gain x bandwidth product of a same diode in the absence of said doped absorption layer.

13. A photodiode as defined in claim 1, wherein the diode is a PIN.

14. A photodiode as defined in claim 1 wherein the diode is an avalanche photodiode.

15. An avalanche photodiode as defined in claim 12 having a separate absorption and multiplication layer.

16. A photodiode as defined in claim 1 with 40 GHz 3-dB bandwidth frequency, wherein the doped and intrinsic absorption layers are InGaAs lattice-matched to InP, and the total thickness of the doped and intrinsic light absorption layers is greater than 0.60 microns.

17. A photodiode as defined in claim 1 with 40 GHz 3-dB bandwidth frequency, wherein the doped and intrinsic absorption layers are InGaAs lattice-matched to InP, and the total thickness of the doped and intrinsic light absorption layers is greater than 0.65 microns.

18. A photodiode as defined in claim 1, with 40 GHz 3-dB bandwidth frequency, wherein the doped and intrinsic absorption layers are InGaAs lattice-matched to InP, and the total thickness of the doped and intrinsic light absorption layers is greater than 0.70 microns.
